(19) United States
(12) Patent Application Publication
(10) Pub. No.: US 2025/0189701 A1
(43) Pub. Date: Jun. 12, 2025

(54) ELECTROMAGNETIC WAVE ABSORBER

(71) Applicant: FUJIFILM Corporation, Tokyo (JP)

(72) Inventors: Taketo OTANI, Kanagawa (JP); Hideki YASUDA, Kanagawa (JP); Yukito SAITOH, Kanagawa (JP); Rikio INOUE, Kanagawa (JP)

(73) Assignee: FUJIFILM Corporation, Tokyo (JP)

(21) Appl. No.: 19/060,042

(22) Filed: Feb. 21, 2025

Related U.S. Application Data
(63) Continuation of application No. PCT/JP2023/034251, filed on Sep. 21, 2023.

(30) Foreign Application Priority Data
Sep. 28, 2022 (JP) 2022-154506

(51) Int. Cl. G02B 5/00

(52) U.S. Cl. CPC G02B 5/003

(57) ABSTRACT

An electromagnetic wave absorber in which a difference in absorption characteristics between a TE wave and a TM wave in a case where electromagnetic waves are incident in an oblique direction is small. The electromagnetic wave absorber includes a reflective layer, a base material layer including a dielectric material or a magnetic material, a microstructure layer including a plurality of microstructures, and an overcoat layer having a refractive index anisotropy in this order.

### CROSS-REFERENCE TO RELATED APPLICATIONS

This application is a Continuation of PCT International Application No. PCT/JP2023/034251 filed on Sep. 21, 2023, which was published under PCT Article 21(2) in Japanese, and which claims priority under 35 U.S.C. § 119(a) to Japanese Patent Application No. 2022-154506 filed on Sep. 28, 2022. The above applications are hereby expressly incorporated by reference, in their entirety, into the present application.

### BACKGROUND OF THE INVENTION

### 1. Field of the Invention

The present invention relates to an electromagnetic wave absorber.

### 2. Description of the Related Art

Radio waves in a frequency band of several gigahertz (GHz) are used in mobile communication, such as mobile phone communication, a wireless LAN, an electronic toll collection system (ETC), and the like.

In recent years, in order to enable an increase of the capacity of data to be transmitted and received, high-speed communication, and multipoint simultaneous connection, the practical application of wireless communication using a higher frequency band has progressed, and the development of devices that enable the practical application has progressed. In addition, in-vehicle radar devices and the like utilizing extremely narrow directivity are being used.

Interference caused by irregular reflection of electromagnetic waves in a housing of a device causes malfunction of the device. Therefore, suppressing electromagnetic wave noise is important as one of the electromagnetic wave utilization technologies.

The use of an electromagnetic wave absorbing sheet is considered to be one method for suppressing the electromagnetic wave noise.

For example, WO2022/107637A proposes an electromagnetic wave attenuation film that is used in a specific millimeter wave frequency band and comprises a dielectric base material having a front surface and a back surface, a thin-film conductive layer disposed on the front surface, and a planar inductor disposed on the back surface. The thin-film conductive layer includes a plurality of metal plates that are discretely disposed.

The electromagnetic wave absorbers installed in electronic devices, building interiors, and the like are continuously used for a long period of time. Therefore, WO2022/107637A proposes a technique for providing a topcoat layer on a surface of the electromagnetic wave attenuation film in order to improve environmental resistance, such as weather resistance and heat resistance, and to match impedance with air to effectively attenuate radio waves.

### SUMMARY OF THE INVENTION

The study of the present inventors shows that, in the absorption of electromagnetic waves as noise by an electromagnetic wave attenuation film, in a case where the electromagnetic waves are incident on the electromagnetic wave attenuation film in an oblique direction, there is a difference in absorption characteristics between a TE wave (orthogonally polarized wave) having a component whose electric field is perpendicular to an incident surface and a TM wave (parallel polarized wave) whose electric field is present in the incident surface.

An object of the present invention is to solve the above-described problems of the related art and to provide an electromagnetic wave absorber in which a difference in absorption characteristics between a TE wave and a TM wave in a case where electromagnetic waves are incident in an oblique direction is small.

In order to achieve the object, the present invention has the following configurations.
[1] An electromagnetic wave absorber comprising, in the following order: a reflective layer; a base material layer including at least one of a dielectric material or a magnetic material; a microstructure layer including a plurality of microstructures; and an overcoat layer having a refractive index anisotropy.
[2] The electromagnetic wave absorber according to claim [1], in which the overcoat layer has the refractive index anisotropy at least in an in-plane direction.
[3] The electromagnetic wave absorber according to [1] or [2], in which a birefringence Δn of the overcoat layer is equal to or greater than 0.2.
[4] The electromagnetic wave absorber according to any one of [1] to [3], in which the overcoat layer includes a liquid crystal compound.
[5] The electromagnetic wave absorber according to any one of [1] to [4], in which an extinction coefficient of the base material layer is equal to or greater than 0.1.
[6] The electromagnetic wave absorber according to any one of [1] to [5], in which, among electromagnetic waves absorbed by the electromagnetic wave absorber, a wavelength that is most absorbed by the electromagnetic wave absorber is in a range of 10 μm to 10 cm.

According to the present invention, it is possible to provide an electromagnetic wave absorber in which a difference in absorption characteristics between a TE wave and a TM wave in a case where electromagnetic waves are incident in an oblique direction is small.

### BRIEF DESCRIPTION OF THE DRAWINGS

FIG. 1 is a view conceptually showing an example of an electromagnetic wave absorber according to an embodiment of the present invention.

FIG. 2 is a side view showing an example of a configuration of a unit cell of the electromagnetic wave absorber according to the embodiment of the present invention.

FIG. 3 is a plan view showing the unit cell shown in FIG. 2.

FIG. 4 is a conceptual view showing polarization of an incident wave.

FIG. 5 is a graph showing a relationship between a birefringence Δn and a range of an incidence angle at which an absorbance is equal to or greater than 97% in a case where a TE wave is incident.

FIG. 6 is a graph showing a relationship between a birefringence Δn and a range of an incidence angle at which an absorbance is equal to or greater than 97% in a case where a TM wave is incident.

FIG. 7 is a view conceptually showing a relationship between the TE wave and a refractive index of a liquid crystal compound.

FIG. 8 is a view conceptually showing a relationship between the TM wave and the refractive index of the liquid crystal compound.

FIG. 9 is a view conceptually showing another example of the electromagnetic wave absorber according to the embodiment of the present invention.

FIG. 10 is a view conceptually showing a relationship between the TE wave and a refractive index of a disk-like liquid crystal compound.

FIG. 11 is a view conceptually showing a relationship between the TM wave and the refractive index of the disk-like liquid crystal compound.

### DESCRIPTION OF THE PREFERRED EMBODIMENTS

Hereinafter, an electromagnetic wave absorber according to an embodiment of the present invention will be described in detail on the basis of preferred examples shown in the accompanying drawings.

In the present specification, a numerical range represented by “to” means a range including numerical values before and after “to” as a lower limit value and an upper limit value.

In the present specification, it is assumed that the term “same” or the like includes an error range that is generally allowable in the technical field.

All of the drawings described below are conceptual views for describing the electromagnetic wave absorber according to the embodiment of the present invention. Therefore, the shape, size, thickness, positional relationship, and the like of each member are not necessarily matched with the actual ones.

### [Electromagnetic Wave Absorber]

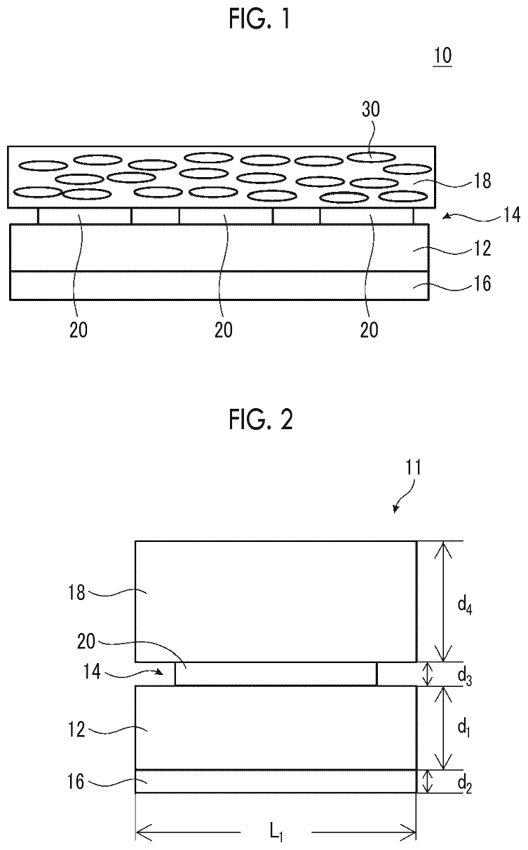

FIG. 1 conceptually shows an example of the electromagnetic wave absorber according to the embodiment of the present invention.

An electromagnetic wave absorber 10 shown in FIG. 1 includes a base material layer 12, a microstructure layer 14 that is disposed on one main surface of the base material layer 12, a reflective layer 16 that is disposed on the other main surface of the base material layer 12, and an overcoat layer 18 that is disposed on a main surface of the microstructure layer 14 that is opposite to the base material layer 12. That is, the electromagnetic wave absorber 10 includes the reflective layer 16, the base material layer 12, the microstructure layer 14, and the overcoat layer 18 in this order.

In the electromagnetic wave absorber 10, the base material layer 12 and the reflective layer 16, the base material layer 12 and the microstructure layer 14, and the microstructure layer 14 and the overcoat layer 18 are bonded to each other using a bonding agent (a pressure sensitive adhesive or an adhesive) as necessary.

A bonding method is not limited, and various known methods in which electromagnetic waves to be absorbed by the electromagnetic wave absorber 10 can be transmitted, such as a method using an optical clear adhesive (OCA) that can transmit the electromagnetic waves to be absorbed by the electromagnetic wave absorber 10, can be used.

### [Base Material Layer]

The base material layer 12 supports the reflective layer 16 and the microstructure layer 14 and includes a dielectric material and/or a magnetic material. Since the base material layer 12 includes the dielectric material and/or the magnetic material, the base material layer 12 converts the electromagnetic waves into heat using the dielectric loss of the dielectric material or the magnetic loss of the magnetic material to absorb the electromagnetic waves.

Here, the dielectric material is a material having dielectricity superior to conductivity. In addition, the magnetic material is a strongly magnetic and/or ferromagnetic material.

The base material layer 12 may be made of a dielectric material or a magnetic material. In addition, the base material layer 12 may be obtained by mixing two or more types of dielectric materials and/or magnetic materials. Alternatively, the base material layer 12 may be obtained by mixing dielectric particles and/or magnetic particles with a binder such as a resin.

Examples of the dielectric material include polyester, such as polyethylene terephthalate (PET), polyarylene sulfide, such as polyphenylene sulfide, polyolefin, such as polyethylene or polypropylene, and resin materials, such as polyamide, polyimide, polyamideimide, polyether sulfone, polyether ether ketone, polycarbonate, acrylic resin, and polystyrene.

In addition, examples of the magnetic material include ferrite and a metal magnetic material.

A thickness of the base material layer 12 is not particularly limited and may be set to any thickness at which a desired absorbance can be obtained by the loss of the base material layer.

### [Reflective Layer]

The reflective layer 16 reflects incident electromagnetic waves. In addition, the reflective layer 16 also acts as an electrode layer.

The reflective layer 16 is not limited, and various known sheet-like materials can be used as long as they can reflect the electromagnetic waves to be absorbed by the electromagnetic wave absorber 10.

For example, in a case where the electromagnetic waves to be absorbed by the electromagnetic wave absorber 10 are electromagnetic waves having a wavelength of 10 μm to 10 cm, examples of the reflective layer 16 include a metal layer, such as copper, aluminum, gold, or silver, an inorganic conductive material, such as indium tin oxide (ITO), an organic conductive material, such as polythiophene, and graphene.

In addition, the reflective layer 16 of the electromagnetic wave absorber 10 may not be necessarily a uniform layer (solid layer) as a whole or may have a structure that provides a uniform reflection distribution in the plane like the uniform layer. For example, the reflective layer 16 may have a metal mesh structure.

The thickness of the reflective layer 16 is not limited, and the thickness at which the target electromagnetic waves can be reflected with a necessary reflectivity may be appropriately set depending on the material forming the reflective layer 16.

### [Microstructure Layer]

The microstructure layer 14 is a so-called meta-surface structure in which a large number of microstructures 20, which are resonators, are arranged on the surface of the base material layer 12. Each of the microstructures 20 acts not only as a reflector but also as an electrode. In the present invention, the microstructure layer 14 is basically a known microstructure layer (metamaterial).

In the example shown in FIG. 1, the microstructure layer 14 has a configuration in which the microstructures 20 are two-dimensionally arranged at regular intervals in the x direction and the y direction which are orthogonal to each other.

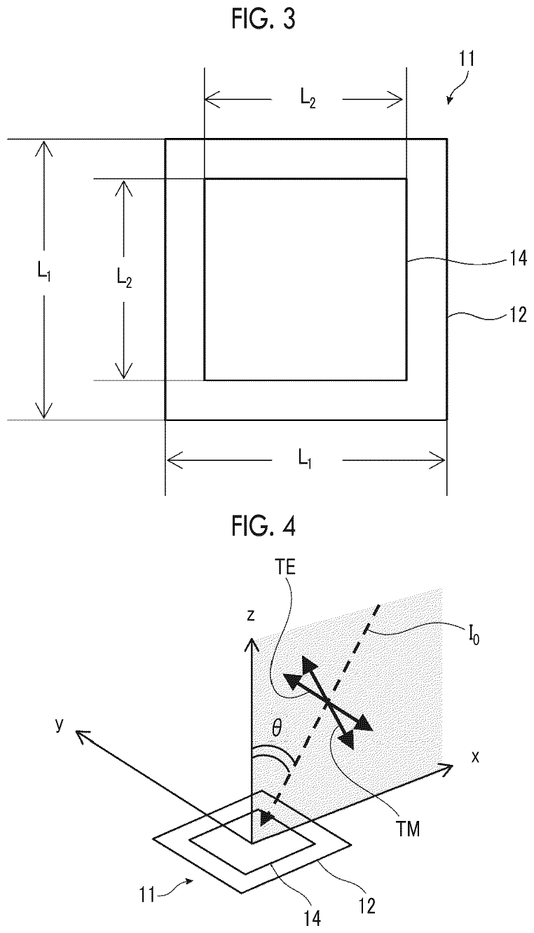

FIG. 2 is a view conceptually showing a unit cell consisting of one microstructure 20 of the microstructure layer 14 and a region around the microstructure 20. FIG. 3 is a plan view (top view) showing the unit cell shown in FIG. 2. In FIG. 3, the overcoat layer 18 is not shown.

It can be said that the electromagnetic wave absorber 10 has a configuration in which the unit cells 11 shown in FIGS. 2 and 3 are two-dimensionally arranged at regular intervals in the x direction and the y direction.

In the unit cell 11 according to the shown example, the microstructure 20 is a rectangular parallelepiped having a square planar shape. In the electromagnetic wave absorber 10 shown in FIG. 1, all of the microstructures 20 have a square planar shape.

In the microstructure layer 14, the shape and forming material of the microstructure 20, the arrangement of the microstructures 20, the interval (pitch) between the microstructures 20, and the like are not limited and may be set in the same manner as in a known microstructure layer.

In addition, the microstructure layer 14 may be designed by a known method according to the desired optical characteristics. As an example, the arrangement of the microstructures 20 and the like may be set using commercially available simulation software such that the electromagnetic waves are absorbed at a target frequency.

Examples of the material forming the microstructure 20 of the microstructure layer 14 include metal and a dielectric material. In a case of the metal, copper, gold, and silver are preferably given as examples from the viewpoint of low optical loss. In addition, silicon, titanium oxide, and germanium are preferably given as examples of the dielectric material.

Examples of the shape of the microstructure 20 include the above-described rectangular parallelepiped shape, a columnar shape, a polygonal prism shapes, such as a triangular prism shape, a solid body with a V-shaped base obtained by connecting rectangular parallelepipeds at ends which is described in JP2018-46395A, a solid body with a cross-shaped base obtained by intersecting rectangular parallelepipeds, a solid body with a substantially H-shaped base, such as an H-beam, and a solid body having a substantially C-shaped bottom surface such as a C-channel.

Further, as described in JP2018-46395A, for the solid body with the V-shaped base and the solid body with the cross-shaped base, various shapes in which an angle formed between two rectangular parallelepipeds is adjusted can be used.

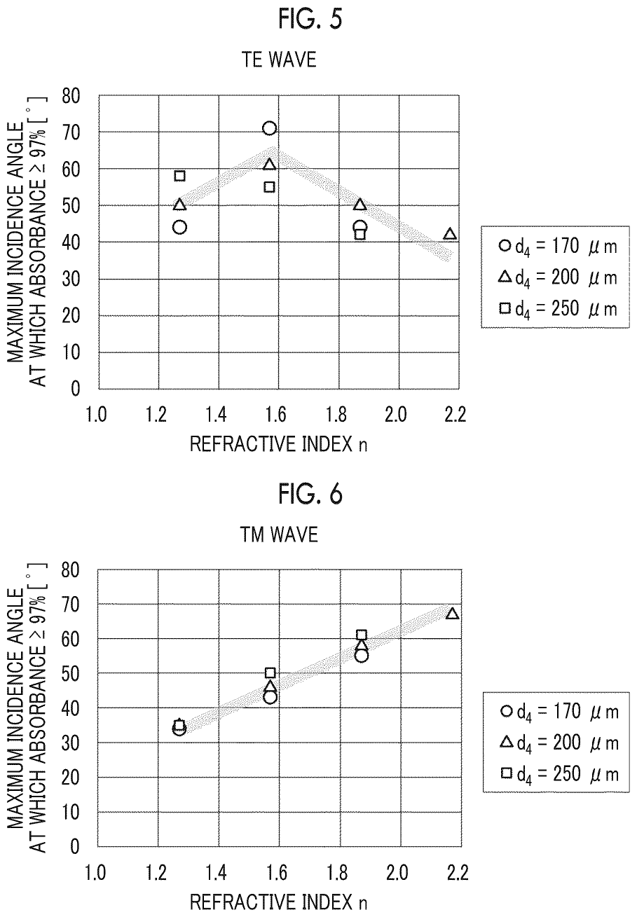

In addition to the above, a solid body having the base shape shown in FIG. 5 of “Appl. Sci. 2018, 8 (9), 1689; https://doi.org/10.3390/app8091689” and the like can be used.

In the microstructure layer 14, only one of the microstructures 20 having these shapes may be used, or two or more of the microstructures 20 may be used in combination.

In addition, the orientations of the same microstructures 20 may be the same or different from each other, or the microstructures 20 with the same orientation and the microstructures 20 with different orientations may be mixed.

The arrangement and interval (pitch) of the microstructures 20 are not limited to the configuration in which the microstructures 20 are arranged at regular intervals in two directions (the x direction and the y direction) orthogonal to each other as described above. For example, the microstructures 20 having different intervals may be present, or the intervals may gradually change in an in-plane direction. In addition, the microstructures 20 may be one-dimensionally arranged.

The thickness of the microstructure 20 is not limited, and the thickness at which the target electromagnetic waves can be reflected with a required reflectivity may be appropriately set depending on the material forming the microstructure 20. It is preferable that the thickness of the microstructure 20 is sufficiently larger than a skin depth d represented by the following expression.

$$d = ( 1 / ( π \cdot f \cdot μ \cdot σ ) ) ⋀ ( 1 / 2 )$$

Here, f indicates the frequency [Hz] of the electromagnetic wave, u indicates the magnetic permeability [H/m] of the microstructure, and σ indicates the conductivity [S/m] of the microstructure.

The thickness of the microstructure 20 is preferably 2 to 3 times the skin depth.

The size of the microstructure 20 in a plan view is not limited, and the microstructure 20 may be set to a size at which the target electromagnetic waves are absorbed, depending on the material forming the microstructure 20 and the like.

### [Overcoat Layer]

The overcoat layer 18 is a layer having a refractive index anisotropy and is disposed on the side of the microstructure layer 14 that is opposite to the base material layer 12.

The overcoat layer 18 having the refractive index anisotropy acts as a layer having different refractive indices for the TE wave and the TM wave of the electromagnetic waves incident on the electromagnetic wave absorber 10 in an oblique direction to reduce a difference in absorption characteristics between the TE wave (orthogonally polarized wave) and the TM wave (parallel polarized wave), which will be described below in detail.

In the example shown in FIG. 1, the overcoat layer 18 is a liquid crystal layer which includes a rod-like liquid crystal compound 30 and in which the crystal compound 30 is aligned and fixed such that a major axis of the liquid crystal compound 30 is aligned in a direction parallel to the main surface of the overcoat layer 18. Therefore, the overcoat layer 18 is a layer having a refractive index anisotropy in which a refractive index of the liquid crystal compound 30 in a major axis direction (a left-right direction in FIG. 1) is different from a refractive index thereof in a minor axis direction (a direction perpendicular to the plane of paper in FIG. 1). That is, the overcoat layer 18 according to the example shown in FIG. 1 has the refractive index anisotropy in the in-plane direction.

In the example shown in FIG. 1, the overcoat layer 18 is configured such that the liquid crystal compound 30 is aligned in the direction parallel to the main surface and has the refractive index anisotropy in the in-plane direction. However, the present invention is not limited to this configuration. The overcoat layer may be configured such that (the major axis of) the liquid crystal compound 30 is aligned in one direction that is obliquely inclined with respect to the main surface or such that the liquid crystal compound 30 is aligned in a direction perpendicular to the main surface.

From the viewpoint of further reducing the difference in absorption characteristics between the TE wave (orthogonally polarized wave) and the TM wave (parallel polarized wave) in the electromagnetic wave absorber 10, it is preferable that the overcoat layer 18 has the refractive index anisotropy at least in the in-plane direction.

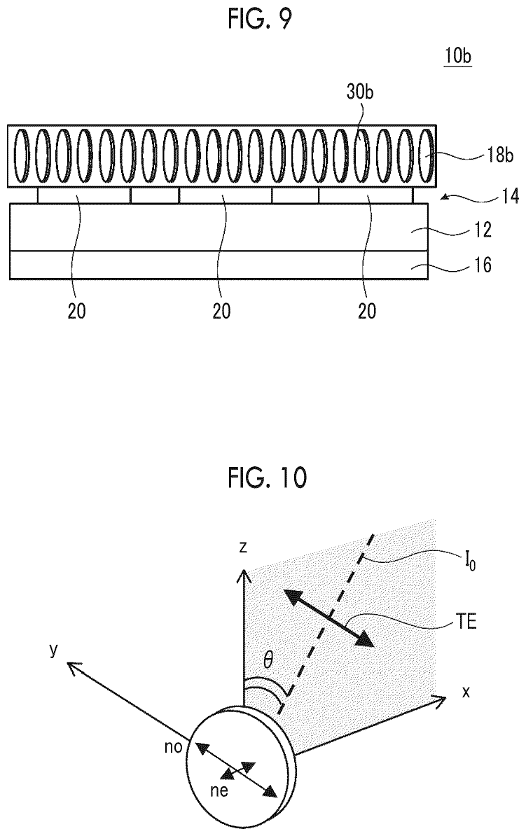

In addition, in the example shown in FIG. 1, the overcoat layer 18 includes the rod-like liquid crystal compound 30. However, the present invention is not limited thereto. The overcoat layer 18 may include a disk-like liquid crystal compound as in an example shown in FIG. 9 which will be described below.

In addition, in the example shown in FIG. 1, the overcoat layer 18 includes the liquid crystal compound 30. However, the present invention is not limited thereto. The overcoat layer 18 may be a stretched film such as polyethylene terephthalate (PET) or polyethylene naphthalate (PEN).

From the viewpoint of further reducing the difference in absorption characteristics between the TE wave (orthogonally polarized wave) and the TM wave (parallel polarized wave), a birefringence Δn of the overcoat layer 18 is preferably equal to or greater than 0.2 and more preferably equal to or greater than 0.3, which will be described in detail below. As Δn increases, it is easier to adjust the refractive index that effectively works on each polarized wave, which is preferable. From the viewpoint of increasing the birefringence Δn, it is preferable that the overcoat layer 18 includes the liquid crystal compound 30.

### Rod-Like Liquid Crystal Compound

As the rod-like liquid crystal compound included in the overcoat layer 18, the following are preferably used: azos; azomethines; azoxys; cyanobiphenyls; cyanophenyl esters; benzoic acid esters; cyclohexanecarboxylic acid phenyl esters; cyanophenylcyclohexanes; cyano-substituted phenylpyrimidines; alkoxy-substituted phenylpyrimidines; phenyldioxanes; tolanes; and alkenylcyclohexylbenzonitriles.

Not only the above-described low-molecular-weight liquid crystalline molecules but also polymer liquid crystalline molecules can be used as the rod-like liquid crystal compound.

In the overcoat layer 18, it is more preferable that the alignment of the rod-like liquid crystal compound is fixed by polymerization. That is, the overcoat layer 18 is preferably a layer formed by polymerizing and fixing a polymerizable rod-like liquid crystal compound.

Examples of the polymerizable rod-like liquid crystal compound include compounds described in Makromol. Chem., (1989), Vol. 190, p. 2255, Advanced Materials (1993), Vol. 5,p. 107, Advanced Photonics Vol. 2, Art. 036002 (2020), U.S. Pat. Nos. 4,683,327A, 5,622,648A, 5,770,107A, WO95/022586A, WO95/024455A, WO97/000600A, WO98/023580A, WO98/052905A, JP1989-272551A (JP-H1-272551A), JP1994-016616A (JP-H6-016616A), JP1995-110469A (JP-H7-110469A), JP1999-080081A (JP-H11-080081A), and JP2001-064627.

Further, for example, compounds described in JP1999-513019A (JP-H11-513019A) and JP2007-279688A can also be preferably used as the rod-like liquid crystal compound.

### Disk-Like Liquid Crystal Compound

For example, compounds described in JP2007-108732A and JP2010-244038A can be preferably used as the disk-like liquid crystal compound.

A liquid crystal layer that becomes the overcoat layer 18 can be formed by applying a composition including a liquid crystal compound onto an alignment film having a desired alignment pattern, drying the composition, and polymerizing the liquid crystal compound as necessary.

Further, in the present invention, an alignment film for aligning the liquid crystal compound 30 may be provided between the overcoat layer 18 and the microstructure layer 14. That is, the alignment film may be provided on the surface of the microstructure layer 14, and the overcoat layer 18 may be formed on the alignment film. Alternatively, a sheet-like material having the alignment film on a support may be used, the overcoat layer 18 may be formed on the alignment film of the sheet-like material, and then the overcoat layer 18 may be peeled off and transferred to the microstructure layer 14.

### Alignment Film

In the present invention, various known alignment films can be used as the alignment film for forming the alignment of the liquid crystal compound 30 constituting the overcoat layer 18 in a thickness direction.

Examples of the alignment film include a rubbed film made of an organic compound, such as a polymer, an obliquely deposited film made of an inorganic compound, a film having a microgroove, and a film formed by accumulating Langmuir-Blodgett (LB) films formed by a Langmuir-Blodgett's method using an organic compound such as ω-tricosanoic acid, dioctadecylmethylammonium chloride, or methyl stearate.

The alignment film formed by a rubbing treatment can be formed by rubbing a surface of a polymer layer with paper or fabric in a predetermined direction multiple times.

Preferred examples of the material used for the alignment film include polyimide, polyvinyl alcohol, a polymer having a polymerizable group described in JP1997-152509A (JP-H9-152509A), and materials used for forming alignment films and the like described in JP2005-97377A, JP2005-99228A, and JP2005-128503A.

The alignment film may be a so-called photo-alignment film obtained by irradiating a photo-alignable material with polarized light or non-polarized light.

Preferable examples of the photo-alignment material used for the photo-alignment film that can be used in the present invention include: an azo compound described in JP2006-285197A, JP2007-076839A, JP2007-138138A, JP2007-094071A, JP2007-121721A, JP2007-140465A, JP2007-156439A, JP2007-133184A, JP2009-109831A, JP3883848B, and JP4151746B; an aromatic ester compound described in JP2002-229039A; a maleimide-and/or alkenyl-substituted nadiimide compound having a photo-alignment unit described in JP2002-265541A and JP2002-317013A; a photocrosslinking silane derivative described in JP4205195B and JP4205198B, a photocrosslinking polyimide, a photocrosslinking polyamide, or a photocrosslinking ester described in JP2003-520878A, JP2004-529220A, and JP4162850B; and a photodimerizable compound, in particular, a cinnamate compound, a chalcone compound, or a coumarin compound described in JP1997-118717A (JP-H9-118717A), JP1998-506420A (JP-H10-506420A), JP2003-505561A, WO2010/150748A, JP2013-177561A, and JP2014-012823A.

Among these, an azo compound, a photocrosslinking polyimide, a photocrosslinking polyamide, a photocrosslinking ester, a cinnamate compound, or a chalcone compound is suitably used.

The thickness of the alignment film is not particularly limited. The thickness at which a required alignment function can be obtained may be appropriately set depending on the material forming the alignment film.

The thickness of the alignment film is preferably 0.01 to 5 μm and more preferably 0.02 to 2 μm.

A method for forming the alignment film is not limited. Various well-known methods corresponding to the material forming the alignment film can be used.

In the present invention, the thickness of the overcoat layer 18 is not limited and may be appropriately set depending on the material forming the overcoat layer 18 and the wavelength of the electromagnetic waves to be absorbed by the electromagnetic wave.

It is preferable that the thickness of the overcoat layer 18 is equal to or greater than 1/10 of the wavelength of the electromagnetic waves to be absorbed by the electromagnetic wave.

### [Action of Electromagnetic Wave Absorber]

Next, the action of the electromagnetic wave absorber 10 according to the embodiment of the present invention having the above-described configuration will be described.

It is considered that the electromagnetic wave absorber 10 absorbs the electromagnetic waves using an action of controlling the amplitude and phase of reflected waves at an interface between the respective layers to reduce the reflected waves and an action of propagating the electromagnetic waves in the base material layer 12 to absorb the electromagnetic waves using the loss of the base material layer 12. Input impedance as the reflective layer is viewed from the surface of the electromagnetic wave absorber may be equal to characteristic impedance of plane waves in order to absorb all of the incident electromagnetic waves.

Here, as described above, it has been found that, in the absorption of the electromagnetic waves as noise by the electromagnetic wave absorber according to the related art, in a case where the electromagnetic waves are incident on the electromagnetic wave absorber in the oblique direction, there is a difference in absorption characteristics between the TE wave (orthogonally polarized wave) having a component whose electric field is perpendicular to an incident surface and the TM wave (parallel polarized wave) whose electric field is in the incident surface (see FIG. 4).

It is considered that the reason is that the input impedance as the reflective layer is viewed from the electromagnetic wave incident surface has different incidence angle dependence between the TE wave and the TM wave as described in Electromagnetic Theory A, Vol. 122, No. 5 (2002) and Introduction to Radio Wave Absorbers (written by Osamu Hashimoto, Morikita Publishing Co., Ltd., 1997).

Therefore, in the electromagnetic wave absorber according to the related art, there is a large difference in absorption characteristics between the TE wave and the TM wave.

In contrast, the electromagnetic wave absorber according to the embodiment of the present invention includes the overcoat layer 18 having a refractive index anisotropy on the microstructure layer 14 that is the incident side of the electromagnetic waves, which makes it possible to reduce the difference in absorption characteristics between the TE wave and the TM wave.

This point will be described using FIGS. 5 and 6.

In a case where the unit cell 11 having a design frequency of 300 GHz was configured as follows and the TE wave or the TM wave was incident in the oblique direction while the refractive index n of the overcoat layer 18 was changed to various values, the maximum incidence angle at which the absorbance was equal to or greater than 97% was calculated by simulation. Here, it was confirmed that the frequency of an absorption peak was shifted forward and backward depending on the refractive index n of the overcoat layer 18, but was in a range of 295 GHz to 315 GHz. COMSOL Multiphysics was used for the simulation. In addition, the absorbance can be calculated by absorbance=(the magnitude of incident electromagnetic waves-the magnitude of transmitted electromagnetic waves-the magnitude of reflected electromagnetic waves)/the magnitude of the incident electromagnetic waves from the magnitude of the electromagnetic waves incident on the electromagnetic wave absorber, the magnitude of the electromagnetic waves transmitted through the electromagnetic wave absorber, and the magnitude of the electromagnetic waves reflected from the electromagnetic wave absorber.

In the configuration of the unit cell 11, a width L₁ (see FIGS. 2 and 3, the same applies below) of the unit cell 11 in the vertical and horizontal directions was set to 350 μm, a thickness d₂ of the reflective layer 16 was set to 1 μm, a thickness di of the base material layer 12 was set to 40 μm, a width L₂ of the microstructure 20 in the vertical and horizontal directions was set to 250 μm, a thickness d₃ of the microstructure 20 was set to 1 μm, and a thickness d₄ of the overcoat layer 18 was set to three types of 170 μm, 200 μm, and 250 μm. In addition, modeling was performed while the reflective layer 16 was made of copper, the base material layer 12 had a refractive index of 1.53 and an extinction coefficient of 0.3, the microstructure 20 was made of copper, and the extinction coefficient of the overcoat layer 18 was 0.

FIG. 5 is a graph showing a relationship between the refractive index n and the maximum incidence angle at which the absorbance is equal to or greater than 97% (hereinafter, also simply referred to as a maximum incidence angle) in a case where the TE wave is incident, which has been calculated by the simulation. FIG. 6 is a graph showing a relationship between the refractive index n and the maximum incidence angle at which the absorbance is equal to or greater than 97% in a case where the TM wave is incident, which has been calculated by the simulation.

As can be seen from FIG. 5, in the case of the TE wave, the relationship between the refractive index n of the overcoat layer and the maximum incidence angle is that the maximum incidence angle has a maximum value at a certain refractive index n and decreases as the refractive index moves away from the maximum value of the refractive index.

On the other hand, as can be seen from FIG. 6, in the case of the TM wave, the relationship between the refractive index n of the overcoat layer and the maximum incidence angle is that the maximum incidence angle increases as the refractive index n increases.

As described above, as can be seen from FIGS. 5 and 6, the relationship between the refractive index n of the overcoat layer 18 and the maximum incidence angle is different between the TE wave and the TM wave. Therefore, for example, in a case where the refractive index of the overcoat layer is isotropic and the refractive index n is 1.57, the maximum incidence angle of the TE wave is about 61°, and the maximum incidence angle of the TM wave is about 46°. In addition, in a case where the refractive index n is 1.87, the maximum incidence angle of the TE wave is about 50°, and the maximum incidence angle of the TM wave is about 58°. As described above, it can be seen that, in the electromagnetic wave absorber according to the related art having the overcoat layer whose refractive index is isotropic, the difference in absorption characteristics between the TE wave and the TM wave is large.

In contrast, in the electromagnetic wave absorber according to the embodiment of the present invention, since the overcoat layer has the refractive index anisotropy, the overcoat layer acts as a layer having different refractive indices for the TE wave and the TM wave. Therefore, it is possible to reduce the difference in absorption characteristics between the TE wave and the TM wave.

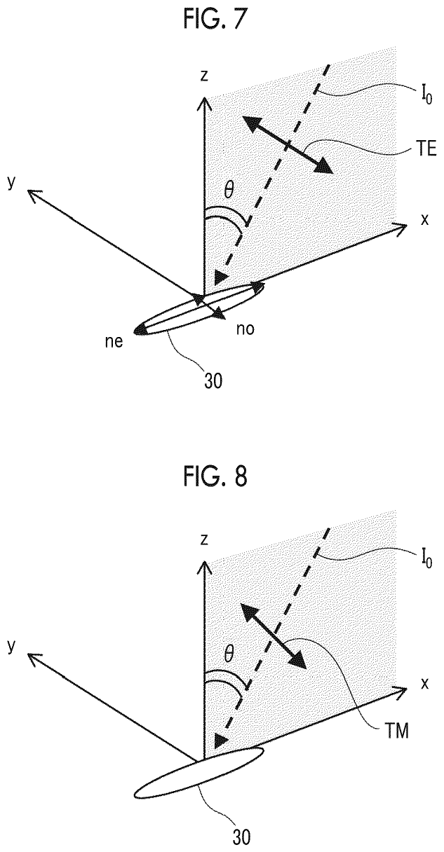

For example, in the overcoat layer including the liquid crystal compound shown in FIG. 1, in a case where an azimuth direction of an incident wave and the direction of the major axis of the liquid crystal compound are aligned with each other, a refractive index no of the liquid crystal compound 30 in the minor axis direction acts on the TE wave of an incident wave Io as shown in FIG. 7, and a refractive index ne of the liquid crystal compound 30 in the major axis direction acts on the TM wave of the incident wave I₀ as shown in FIG. 8. Therefore, in the example of the configuration in which the simulation is performed, a rod-like liquid crystal compound having a refractive index no of 1.57 and a refractive index ne of 1.87 is used as the liquid crystal compound included in the overcoat layer, which makes it possible to set the maximum incidence angle of the TE wave to about 61° from FIG. 5 and to set the maximum incidence angle of the TM wave to about 58° from FIG. 6. As described above, since the electromagnetic wave absorber according to the embodiment of the present invention includes the overcoat layer having the refractive index anisotropy, it is possible to reduce the difference in absorption characteristics between the TE wave and the TM wave incident in the oblique direction. It is presumed that the reason is that the effective permittivity for each of the TE wave and the TM wave is changed by the refractive index anisotropy of the overcoat layer to make the input impedance as the reflective layer is viewed from the surface of the electromagnetic wave absorber close to the characteristic impedance of the plane wave as described above, resulting in an increase in absorbance.

Further, in the above-described example, the refractive index of the overcoat layer in the direction perpendicular to the incident surface is set to a refractive index (=1.57) close to the refractive index at which the maximum incidence angle has the maximum value in the graph in the case of the TE wave shown in FIG. 5, and the refractive index of the overcoat layer in the direction parallel to the incident surface is set to a refractive index (=1.87) at which the maximum incident angle is substantially the same as the maximum value of the maximum incidence angle of the TE wave in the graph in the case of the TM wave shown in FIG. 6. However, the present invention is not limited thereto. As the refractive index of the overcoat layer in the direction perpendicular to the incident surface and the refractive index of the overcoat layer in the direction parallel to the incident surface, a refractive index having a value at which the maximum incidence angle of the TE wave and the maximum incidence angle of the TM wave are close to each other may be appropriately set.

From the viewpoint of further increasing the maximum incidence angle, it is preferable that the refractive index of the overcoat layer in the direction perpendicular to the incident surface is a refractive index at which the maximum incidence angle of the TE wave has the maximum value, and the refractive index of the overcoat layer in the direction parallel to the incident surface is a refractive index at which the maximum incidence angle is substantially the same as the maximum value of the maximum incidence angle of the TE wave.

Here, as described above, in the case of the TE wave, the relationship between the refractive index of the overcoat layer and the maximum incidence angle is that the maximum incidence angle has the maximum value at a certain refractive index and decreases as the refractive index moves away from the maximum value of the refractive index (FIG. 5). On the other hand, in the case of the TM wave, the relationship between the refractive index of the overcoat layer and the maximum incidence angle is that the maximum incidence angle increases as the refractive index increases (FIG. 6). Therefore, in a case where the birefringence Δn of the overcoat layer is small, it is difficult to appropriately set each of the maximum incidence angle of the TE wave and the maximum incidence angle of the TM wave. From the viewpoint appropriately setting the maximum incidence angle of the TE wave and the maximum incidence angle of the TM wave, it is preferable that the birefringence Δn of the overcoat layer is large. From FIGS. 5 and 6, from the viewpoint of setting the refractive index in the direction parallel to the incident surface to the refractive index at which the maximum incidence angle is substantially the same as the maximum incidence angle of the TE wave, the birefringence Δn of the overcoat layer is preferably equal to or greater than 0.2 and more preferably equal to or greater than 0.3.

In addition, in the example shown in FIG. 1, the overcoat layer is a layer including the rod-like liquid crystal compound. However, the present invention is not limited thereto, and the overcoat layer may be a layer including a disk-like liquid crystal compound.

FIG. 9 is a view conceptually showing another example of the electromagnetic wave absorber according to the embodiment of the present invention.

An electromagnetic wave absorber 10b shown in FIG. 9 includes the base material layer 12, the microstructure layer 14 that is disposed on one main surface of the base material layer 12, the reflective layer 16 that is disposed on the other main surface of the base material layer 12, and an overcoat layer 18b that is disposed on a main surface of the microstructure layer 14 opposite to the base material layer 12. That is, the electromagnetic wave absorber 10b includes the reflective layer 16, the base material layer 12, the microstructure layer 14, and the overcoat layer 18b in this order. The electromagnetic wave absorber 10b shown in FIG. 9 has the same configuration as the electromagnetic wave absorber 10 shown in FIG. 1 except that it includes the overcoat layer 18b instead of the overcoat layer 18. Therefore, in the following description, different portions will be mainly described.

The overcoat layer 18b is a liquid crystal layer which includes a disk-like liquid crystal compound 30b and in which a molecular axis of the disk-like liquid crystal compound 30b is aligned and fixed in one direction parallel to a main surface of the overcoat layer 18b. The molecular axis of the disk-like liquid crystal compound 30b is an axis perpendicular to a disk plane. Therefore, as shown in FIG. 9, in the disk-like liquid crystal compound 30b, the disk plane is aligned perpendicularly to the main surface of the overcoat layer 18b.

Therefore, the overcoat layer 18b is a layer having a refractive index anisotropy in which a refractive index of the disk-like liquid crystal compound 30b in a molecular axis direction (a left-right direction in FIG. 9) is different from a refractive index thereof in a direction orthogonal to the molecular axis (a direction perpendicular to the plane of paper in FIG. 1).

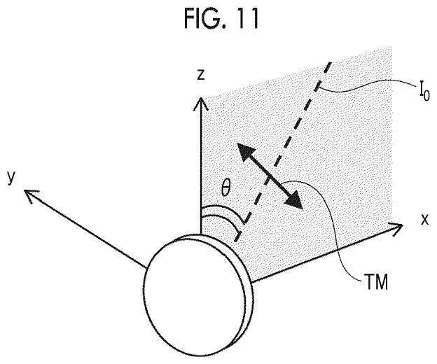

As shown in FIG. 9, in the overcoat layer including the disk-like liquid crystal compound, in a case where the azimuth direction of an incident wave is aligned with the direction of the molecular axis of the liquid crystal compound, the refractive index no of the disk-like liquid crystal compound 30b in a disk plane direction acts on the TE wave of the incident wave Io as shown in FIG. 10, and the refractive index ne of the disk-like liquid crystal compound 30b in a direction perpendicular to the disk plane acts on the TM wave of the incident wave Io as shown in FIG. 11. Therefore, the disk-like liquid crystal compound included in the overcoat layer is appropriately selected, which makes it possible to appropriately select the refractive index for to the TE wave and the refractive index for the TM wave and to appropriately select the maximum incidence angle of the TE wave and the maximum incidence angle of the TM wave. Therefore, it is possible to reduce the difference in absorption characteristics between the TE wave and the TM wave incident in the oblique direction. For example, the disk-like liquid crystal compound having a refractive index ne of 1.57 and a refractive index no of 1.87 is used to set the refractive index of the overcoat layer in the direction perpendicular to the incident surface to 1.87 and to set the refractive index of the overcoat layer in the direction parallel to the incident surface to 1.57. In this case, the maximum incidence angle of the TE wave is about 50°, and the maximum incidence angle of the TM wave is about 48°. The maximum incidence angle of the TE wave and the maximum incidence angle of the TM wave can be close to each other.

In addition, the extinction coefficient of the base material layer is preferably equal to or greater than 0.1.

As described above, the electromagnetic wave absorber according to the embodiment of the present invention has an action of propagating the electromagnetic waves in the base material layer to absorb the electromagnetic waves as one of the actions of absorbing the electromagnetic waves. The absorption in a case where the electromagnetic waves are propagated in the base material layer and are absorbed depends on the extinction coefficient of the base material layer. The extinction coefficient is a parameter indicating the loss of energy of light in a material. As the extinction coefficient is larger, the amount of absorption in a case where light travels through the material is larger. Therefore, the extinction coefficient of the base material layer is preferably equal to or greater than 0.1 and more preferably equal to or greater than 0.2.

The wavelength of the electromagnetic wave to be absorbed by the electromagnetic wave absorber 10 according to the embodiment of the present invention is not limited, and electromagnetic waves having various wavelengths including visible light can be used as the object to be absorbed. Among these electromagnetic waves absorbed by the electromagnetic wave absorber, a preferred example of the wavelength that is most absorbed by the electromagnetic wave absorber is a wavelength in a range of 10 μm to 10 cm.

The electromagnetic wave absorber according to the embodiment of the present invention has been described in detail above. However, the present invention is not limited to the above-described examples. Of course, various improvements and modifications may be made without departing from the gist of the present invention.

### EXAMPLES

Hereinafter, the characteristics of the present invention will be described in detail using examples.

In addition, the following examples show examples of the present invention. Therefore, the present invention should not be construed as being limited to the following specific examples.

### Example 1

### [Production of Electromagnetic Wave Absorber]

An electromagnetic wave absorber described below was produced by optical simulation. Finite element method simulation software “COMSOL Multiphysics” manufactured by COMSOL Inc. was used for the simulation.

A base material layer that has a thickness of 40 μm and includes a dielectric material having a refractive index of 1.53 and an extinction coefficient of 0.3 was prepared. A copper reflective plate having a thickness of 1 μm was disposed on a back surface of the base material layer. In addition, a microstructure layer, in which a square microstructure that was made of copper, had a thickness of 1 μm and a side length of 250 μm was arranged, was disposed on a front surface of the base material layer. In addition, as conceptually shown in FIGS. 2 and 3, one unit cell was configured to have a square shape of 350 μm×350 μm, and one microstructure was disposed at the center of the unit cell. A design resonant frequency was set to 300 GHz (wavelength: 1000 μm).

An overcoat layer that had refractive index anisotropy and had a thickness of 200 μm and an in-plane birefringence Δn of 0.3 (ne=1.87, no=1.57) was formed on a surface, which was opposite to the base material layer, in the microstructure layer formed on the base material layer, thereby producing an electromagnetic wave absorber. In addition, the overcoat layer was disposed such that an incident surface was the x-z plane of FIG. 7, ne was parallel to the x-axis, and no was parallel to the y-axis.

### Example 2

An electromagnetic wave absorber was prepared in the same manner as in Example 1, except that the birefringence Δn of the overcoat layer was set to −0.3 (ne=1.57, no=1.87).

### Comparative Example 1

An electromagnetic wave absorber was prepared in the same manner as in Example 1, except that the birefringence Δn of the overcoat layer was set to 0 (n=1.87).

### Comparative Example 2

An electromagnetic wave absorber was prepared in the same manner as in Example 1, except that the birefringence Δn of the overcoat layer was set to 0 (n=1.57).

### [Evaluation]

The absorbance was calculated by simulation while changing the incidence angle of an incident wave incident on the electromagnetic wave absorber in the x-z plane (incident surface) at an interval of 10°. The absorbance for each of the TE wave and the TM wave was calculated while changing the frequency of the incident wave at an interval of 5 GHz in a range of 200 GHz to 400 GHz. At the frequency at which the absorption was maximized at an incidence angle of 0°, the maximum value of the incidence angle at which the absorbance was equal to or greater than 97% was calculated as the maximum incidence angle from the calculated absorbance. In addition, a difference between the maximum incidence angle of the TE wave and the maximum incidence angle of the TM wave was calculated.

The results are shown in Table 1.

TABLE 1

| | Overcoat layer | | | Evaluation | | | |
|---|---|---|---|---|---|---|---|
| | Refractive index | | | Absorption | Maximum incidence angle | | |
| | ne | no | Δn | frequency GHz | TE wave | TM wave | Difference |
| Example 1 | 1.87 | 1.57 | 0.3 | 310 | 61° | 57° | 4° |
| Example 2 | 1.57 | 1.87 | −0.3 | 300 | 50° | 48° | 2° |
| Comparative | 1.87 | 1.87 | 0 | 295 | 50° | 58° | 8° |
| Example 1 | | | | | | | |
| Comparative | 1.57 | 1.57 | 0 | 315 | 61° | 46° | 15° |
| Example 2 | | | | | | | |

As can be seen from Table 1, in the electromagnetic wave absorber according to Example 1, the maximum incidence angles of both the TE wave and the TM wave are large, and the difference is a small value of 4°. In addition, in Example 2, it can be seen that the maximum incidence angles of both the TE wave and the TM wave are small, and the difference therebetween is a small value of 2°.

On the other hand, in Comparative Examples 1 and 2, it can be seen that the maximum incidence angle of one of the TE wave and the TM wave is large, the maximum incidence angle of the other is small, and the differences are large values of 8° and 15°, respectively.

As described above, it can be seen that, in the electromagnetic wave absorber according to the embodiment of the present invention, the difference in absorption characteristics between the TE wave and the TM wave is smaller than that in the comparative examples. In addition, it can be seen that the angle range of absorption can be adjusted to any value in the electromagnetic wave absorber according to the embodiment of the present invention.

The effects of the present invention are obvious from the above results.

### EXPLANATION OF REFERENCES

10, 10b: electromagnetic wave absorber
11: unit cell
12: base material layer
14: microstructure layer
16: reflective layer
18, 18b: overcoat layer
20: microstructure
30: (rod-like) liquid crystal compound
30b: disk-like liquid crystal compound

What is claimed is:

1. An electromagnetic wave absorber comprising, in the following order:
a reflective layer;
a base material layer including at least one of a dielectric material or a magnetic material;
a microstructure layer including a plurality of microstructures; and
an overcoat layer having a refractive index anisotropy.

2. The electromagnetic wave absorber according to claim 1,
wherein the overcoat layer has the refractive index anisotropy at least in an in-plane direction.

3. The electromagnetic wave absorber according to claim 1,
wherein a birefringence Δn of the overcoat layer is equal to or greater than 0.2.

4. The electromagnetic wave absorber according to claim 1,
wherein the overcoat layer includes a liquid crystal compound.

5. The electromagnetic wave absorber according to claim 1,
wherein an extinction coefficient of the base material layer is equal to or greater than 0.1.

6. The electromagnetic wave absorber according to claim 1,
wherein, among electromagnetic waves absorbed by the electromagnetic wave absorber, a wavelength that is most absorbed by the electromagnetic wave absorber is in a range of 10 μm to 10 cm.

7. The electromagnetic wave absorber according to claim 2,
wherein a birefringence Δn of the overcoat layer is equal to or greater than 0.2.

8. The electromagnetic wave absorber according to claim 2,
wherein the overcoat layer includes a liquid crystal compound.

9. The electromagnetic wave absorber according to claim 2,
wherein an extinction coefficient of the base material layer is equal to or greater than 0.1

10. The electromagnetic wave absorber according to claim 2,
wherein, among electromagnetic waves absorbed by the electromagnetic wave absorber, a wavelength that is most absorbed by the electromagnetic wave absorber is in a range of 10 μm to 10 cm.

11. The electromagnetic wave absorber according to claim 3,
wherein the overcoat layer includes a liquid crystal compound.

12. The electromagnetic wave absorber according to claim 3,
wherein an extinction coefficient of the base material layer is equal to or greater than 0.1.

13. The electromagnetic wave absorber according to claim 3,
wherein, among electromagnetic waves absorbed by the electromagnetic wave absorber, a wavelength that is most absorbed by the electromagnetic wave absorber is in a range of 10 μm to 10 cm.

14. The electromagnetic wave absorber according to claim 4,
wherein an extinction coefficient of the base material layer is equal to or greater than 0.1.

15. The electromagnetic wave absorber according to claim 4,
wherein, among electromagnetic waves absorbed by the electromagnetic wave absorber, a wavelength that is most absorbed by the electromagnetic wave absorber is in a range of 10 μm to 10 cm.

16. The electromagnetic wave absorber according to claim 5,
wherein, among electromagnetic waves absorbed by the electromagnetic wave absorber, a wavelength that is most absorbed by the electromagnetic wave absorber is in a range of 10 μm to 10 cm.
